(19) United States
(12) Patent Application Publication
(10) Pub. No.: US 2014/0091846 A1
(43) Pub. Date: Apr. 3, 2014

(54) INTEGRATED COMPARATOR WITH HYSTERESIS, IN PARTICULAR PRODUCED IN AN FD SOI TECHNOLOGY

(71) Applicant: STMicroelectronics SA, Montrouge (FR)

(72) Inventor: Francois Agut, Saint Vital (FR)

(73) Assignee: STMICROELECTRONICS SA, Montrouge (FR)

(21) Appl. No.: 14/040,781

(22) Filed: Sep. 30, 2013

(30) Foreign Application Priority Data
Oct. 1, 2012 (FR) 1259273

(51) Int. Cl. H03K 3/3565

(52) U.S. Cl. CPC H03K 3/3565
USPC 327/206

(57) ABSTRACT

A comparator circuit includes an input differential amplifier circuit generating an output signal and an inverting output circuit generating a complemented output signal. The differential amplifier circuit is formed of a differential pair of input transistors and a pair of diode connected load transistors. The comparator circuit is integrated in a silicon on insulator type structure. A hysteresis-creating circuit is formed by coupling one or more of the output signal and complemented output signal to a substrate region (in the silicon on insulator type structure) associated with one or more of the differential pair of input transistors and pair of diode connected load transistors. The differential amplifier circuit may further include auxiliary transistors coupled to the diode connected load transistors and the hysteresis-creating circuit may further couple one or more of the output signal and complemented output signal to the substrate region associated with the auxiliary transistor.

### PRIORITY CLAIM

This application claims priority from French Application for Patent No. 1259273 filed Oct. 1, 2012, the disclosure of which is incorporated by reference.

### TECHNICAL FIELD

The invention relates to integrated comparators with hysteresis, in particular, but not exclusively, to such comparators produced in a technology of fully depleted silicon on insulator (FD SOI) type.

### BACKGROUND

FIG. 1 schematically illustrates a conventional structure of a comparator with hysteresis produced in a bulk substrate technology.

More specifically, the comparator comprises a differential pair of input transistors T1, T2, here PMOS transistors, comprising a reference input Eref intended to receive a reference voltage Vref and a signal input ES for receiving a voltage V to be compared with said reference voltage.

The comparator CMP also comprises an output stage ETS, here formed by an inverter. This output stage comprises a signal output OUT and a complemented signal output NOUT.

The comparator CMP also comprises hysteresis-creating means coupled between the differential input pair T1, T2 and the output stage ETS.

The hysteresis-creating means here comprise, conventionally, a pair of transistors T3, T4 cross-coupled by their gates and drains, and connected to the differential input pair T1, T2. A first current mirror T6, T8 copies the difference between the current (which depends on the voltage V) circulating in the branch T2 and that (which depends on the reference voltage) circulating in the branch T4, in the branch connected to the output OUT.

Symmetrically, a second current mirror T5, T7 and a third current mirror T9, T10 copy the difference between the current circulating in the branch T1 and that circulating in the branch T3, in that linking the transistor T10 to the output OUT.

The fact that these current differences depend on the voltages V and Vref results in a hysteresis at the time of the comparison.

The comparator CMP also comprises conventional biasing means MPL here comprising transistors T20, T21 and T22 associated with a variable resistor R that can be used to adjust the bias current.

Such a structure has the drawback of offering hysteresis-creating means that require a large number of transistors. Furthermore, depending on the desired hysteresis value, the number of memory effect transistors T3, T4 can be even greater.

### SUMMARY

According to one embodiment, an integrated comparator with hysteresis is proposed that requires a smaller number of transistors to create the hysteresis.

According to one aspect, an integrated comparator with hysteresis is proposed that comprises a differential pair of input transistors, an output stage comprising a signal output and a complemented signal output, and hysteresis-creating means coupled between the differential input pair and the output stage.

According to a general feature of this aspect, the comparator is produced in a technology of silicon on insulator (SOI) type, preferentially but not exclusively in a technology of fully depleted silicon on insulator (FD SOI) type, notably because of its low consumption and the greater thinness of the layer of silicon topping the buried insulating layer; moreover, the hysteresis-creating means comprise a differential pair of groups of transistors mounted in diode mode connected in series with the differential input pair; each group of the differential pair comprises at least one transistor mounted in diode mode. In practice, in some applications, it is sufficient to provide just one transistor mounted in diode mode for each group. In other applications requiring a greater hysteresis value, it may be advantageous to provide, in each group, either a transistor mounted in diode mode of larger size, or several transistors mounted in diode mode mutually connected in parallel.

Moreover, at least one transistor taken from the input transistors and the transistors mounted in diode mode has its substrate connected to one of the signal outputs.

Thus, in this aspect, there is a saving, compared to the prior art structure, on the memory-effect transistors connected by being coupled by their gate. In practice, the hysteresis is created here by the threshold voltage difference between the MOS transistors because of the direct coupling of their substrate by the potential of one of the signal outputs.

According to one embodiment, the transistors mounted in diode mode have a conductivity type opposite to that of the transistors of the differential input pair and the hysteresis-creating means also comprise: a first auxiliary transistor connected to one of the signal outputs and forming, with one of the groups of transistors mounted in diode mode, a first current-copying means, a second auxiliary transistor forming, with the other group of transistors mounted in diode mode, a second current-copying means, and a third current-copying means connected between the second current-copying means and said one of the signal outputs;

The hysteresis can be obtained by the threshold voltage difference between MOS transistors that have their wells directly biased by the signal outputs of the output stage.

That being the case, generally, the hysteresis can be obtained by coupling just one of the transistors of a differential pair (an input transistor or else a transistor mounted in diode mode) to one of the signal outputs.

A hysteresis will then be obtained either in the rising phase or in the falling phase, which will not necessarily be symmetrical in relation to the reference voltage, that is to say that the voltage offset relative to the reference voltage will not necessarily be identical in the rising phase and in the falling phase.

That being the case, in practice, if the aim is to have a symmetrical hysteresis effect in the rising phase and in the falling phase relative to the reference voltage, it is then preferable to connect the substrates of the two transistors of the differential pair concerned to the signal output and to the complemented signal output, respectively.

Thus, according to one advantageous embodiment, the transistor or transistors mounted in diode mode of one of the groups has/have its/their substrate linked to the signal output and the transistor or transistors mounted in diode mode of the other group has/have its/their substrate connected to the complemented signal output.

It is also possible to increase the value of the hysteresis by connecting the substrate of at least one auxiliary transistor to at least one of the signal inputs.

Thus, according to one embodiment, the auxiliary transistor, connected to the group of at least one transistor mounted in diode mode that has its substrate connected to one of the signal outputs, has its substrate connected to the other signal output.

So as to increase the gain of the comparator, it is also possible to also connect the substrate of at least one of the input transistors to one of the signal outputs.

More specifically, according to one embodiment, the input transistor, connected to the group of at least one transistor mounted in diode mode that has its substrate connected to one of the signal outputs, has its substrate connected to the other signal output.

The transistors of the differential input pair can be PMOS transistors or else NMOS transistors and the transistors mounted in diode mode can then be NMOS transistors or PMOS transistors.

In an embodiment, an integrated comparator with hysteresis comprises: a differential pair of input transistors; an output stage comprising a signal output and a complemented signal output; a pair of transistors each mounted in diode mode and coupled between the differential pair of input transistors and the output stage; a silicon on insulator type structure integrating said differential pair of input transistors, output stage and pair of transistors mounted in diode mode; and a hysteresis-creating circuit comprising a circuit connection of at least one of said signal output or complemented signal output to a substrate of the silicon on insulator type structure associated with at least one transistor of the differential pair of transistors or pair of transistors mounted in diode mode.

In an embodiment, a circuit comprises: a differential amplifier circuit configured to function as a comparator and generate an output signal and a complemented output signal, said differential amplifier circuit including a transistor having a gate, a source, a drain and a well; a silicon on insulator type structure integrating said differential amplifier circuit, said silicon on insulator type structure include a first semiconductor layer including said source and drain, a second semiconductor layer including said well, and an insulating layer separating said first and second semiconductor layers; and a hysteresis-creating circuit comprising a circuit connection of at least one of said signal output or complemented signal output to the well in the second semiconductor layer.

In an embodiment, a method comprises: receiving input signals at inputs of a differential amplifier circuit functioning as a comparator and generating an output signal and a complemented output signal; and creating hysteresis in the comparator by applying at least one of said output signal or complemented output signal to a substrate of a silicon on insulator type structure integrating said differential amplifier circuit.

### BRIEF DESCRIPTION OF THE DRAWINGS

Other advantages and features of the invention will become apparent on studying the detailed description of nonlimiting embodiments, and the appended drawings in which:

FIG. 1, already described, illustrates an example of a comparator with hysteresis according to the prior art,

FIGS. 2 to 5 schematically illustrate a topology of an MOS transistor produced in FD technology, and

FIGS. 6 to 9 schematically illustrate different embodiments of a comparator with hysteresis according to the invention.

### DETAILED DESCRIPTION OF THE DRAWINGS

In contrast to a bulk substrate technology, the technology of the fully depleted silicon on insulator (FD-SOI) type relies on the principle of the deposition of a very thin layer of silicon on a buried layer of insulating oxide supported by a bottom substrate layer. Such a technology offers properties of low consumption and of operation with very low power supply voltage.

In the FD SOI technology, there are two possible embodiments, namely a so-called “flip well” (FW, a term well known to the person skilled in the art) embodiment and a “no flip well” (NFW) embodiment.

The distinction between these two embodiments (flip well and no flip well) is made by the type of conductivity of the well situated under the buried insulating region and under the transistor.

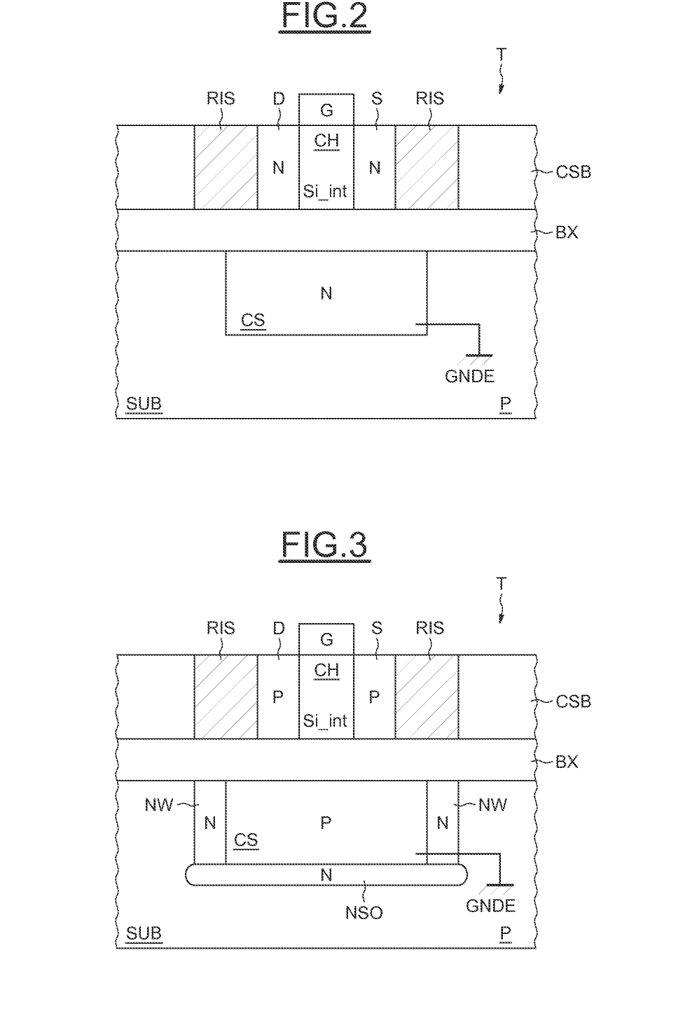

FIG. 2 illustrates a production of an NMOS transistor T in FD SOI with flip well (FD SOI FW) technology.

The bottom substrate layer SUB is here of conductivity type P and supports the buried oxide layer BX which in turn supports the thin top layer of silicon CSB. Together, these three layers form a so-called “silicon on insulator” (SOI) substrate.

The transistor T is produced in the top substrate layer CSB inside an insulating region RIS, for example of the shallow trench insulation (STI) type. The RIS trenches extend to the buried oxide layer BX.

The transistor conventionally comprises N-doped drain and source regions and a gate G which can be, for example, either N-doped or metallic.

The drain and source regions also extend to the buried layer BX. The substrate is here fully depleted because the channel region CH situated under the gate and which extends to the buried layer BX is a region of intrinsic silicon Si_int, that is to say non-doped. The well CS situated within the bottom substrate SUB under the buried oxide layer BX and under the transistor T is here of conductivity type N. This is why the term flip well technology is used here. This well CS is generally biased to the ground but it can also be biased to a high potential, for example to the power supply voltage.

In an FD SOI technology, the channel CH can thus be controlled on the one hand by the potential applied to the insulated gate G, and on the other hand by the potential of the well CS.

It should be noted here that a high biasing of the well CS in relation to a biasing of the substrate SUB to the ground does not pose any problem because the diode NP between the well CS and the substrate SUB is then a reverse diode.

The transistor T exhibits a threshold voltage Vt that differs according to the bias of the well CS.

Thus, as an indication, between a bias to the ground of the well CS and a bias to the power supply voltage VDDE (for example of the order of 1.2 to 1.5 volts), the threshold voltage difference is of the order of 150 millivolts.

It will be seen in more detail hereinbelow that the different embodiments will use this threshold voltage difference between transistors that have their well biased differently to create the hysteresis of the comparator.

FIG. 3 schematically illustrates the production of a PMOS transistor T in FD SOI with flip well (FW) technology.

Compared to the embodiment of FIG. 2, the drain and source regions of the transistor are this time P-doped. The insulated gate G can be P-doped or else metallic.

The underlying well CS is this time of conductivity type P. It is generally biased to the ground GNDE. That being the case, its potential can also be higher than that of the underlying substrate SUB. This is why the well CS is generally insulated from the underlying substrate SUB. This insulation can be produced, for example, by wells NW and a buried layer NSO of conductivity types N.

It then becomes possible to raise the biasing of the well CS to the power supply voltage VDDE.

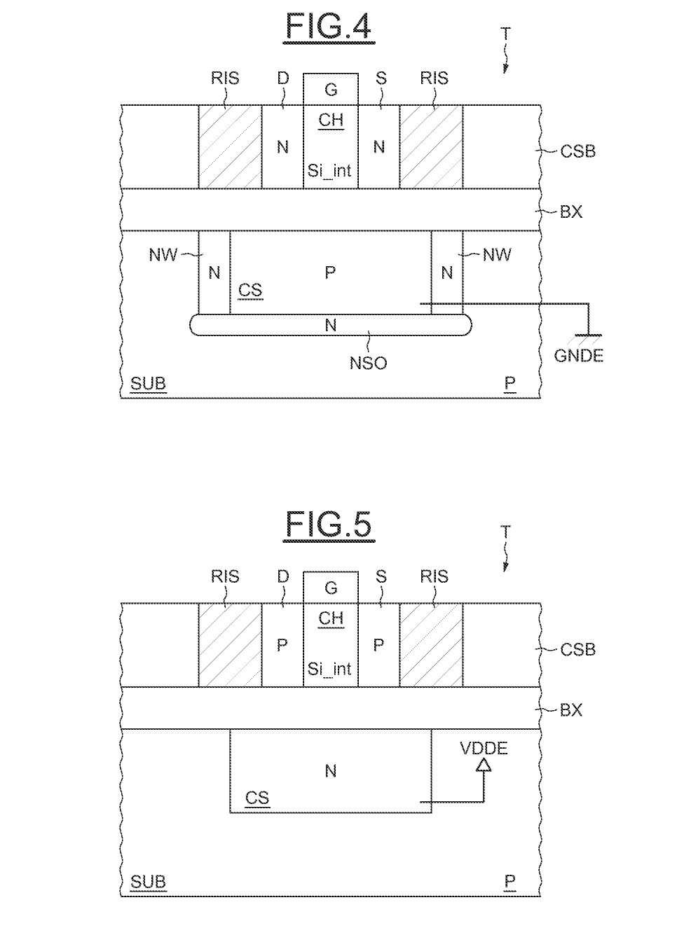

FIG. 4 schematically illustrates a production of an NMOS transistor T in FD SOI with no flip well (NFW) technology. The production of the NMOS transistor of FIG. 4 is similar to that of the PMOS transistor of FIG. 3, apart from the fact that the source and drain regions D and S of the NMOS transistor are N-doped and the insulated gate G can also be N-doped.

Here again, the well CS of the transistor T of FIG. 4 can be biased to the ground GNDE and optionally raised to the power supply voltage VDDE.

FIG. 5 schematically illustrates the production of a PMOS transistor in FD SOI with no flip well (NFW) technology. The structure of the PMOS transistor T of FIG. 5 is similar to the structure of the NMOS transistor of FIG. 2, apart from the doping of the drain/source and gate regions.

The underlying well CS of N type of the transistor T of FIG. 5 is generally biased to the power supply voltage VDDE but can also be biased to the ground.

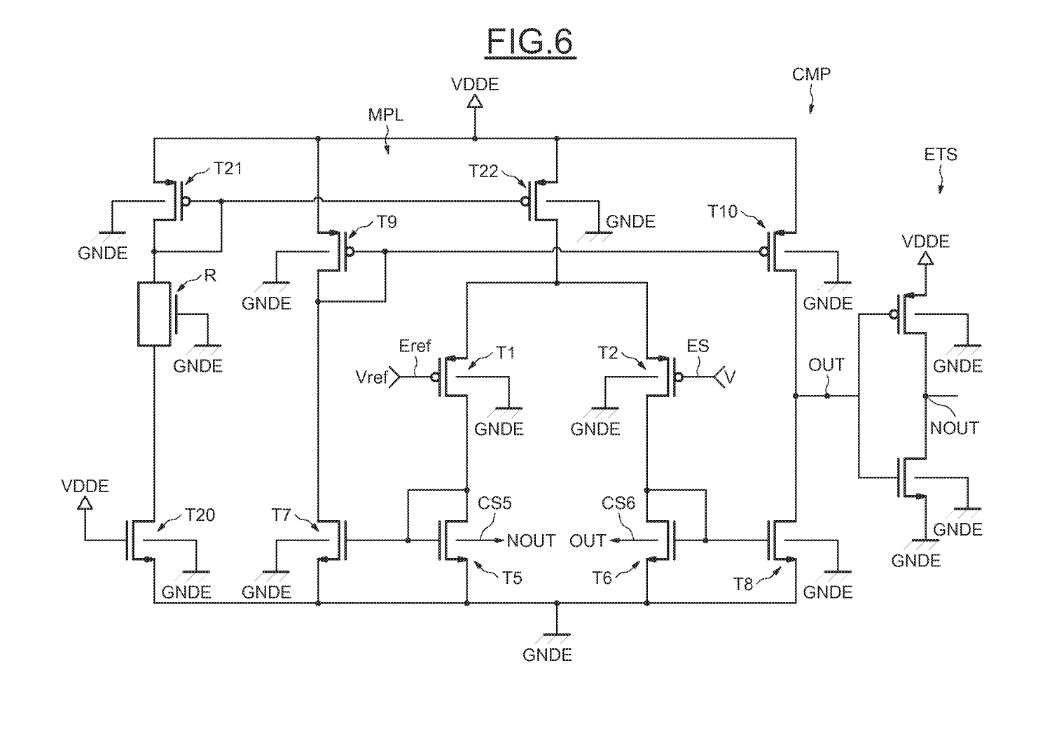

Reference is now made more particularly to FIGS. 6 to 9 to illustrate different embodiments of a comparator CMP according to the invention.

In these embodiments, the comparator CMP is produced in FD SOI technology.

That being the case, although the FD SOI technology is of particular interest, the comparator according to the invention can also be produced more generally in SOI technology.

Also, hereinafter in the description, when reference is made to the biasing of the substrate of a transistor, it is actually the biasing of the substrate of the transistor when it is produced in a technology of SOI type, or else the biasing of the underlying well CS when it is produced in FD SOI technology.

In FIG. 6, the comparator CMP is produced in FD SOI FW technology.

Thus, in this technology, apart from the biasing of the transistors T5 and T6, to which we will be returning in more detail, the substrates of the PMOS transistors are biased to the ground GNDE as are the substrates of the NMOS transistors.

It should be noted in this respect that, in this embodiment, since the wells of the PMOS transistors, notably the transistors T1 and T2, remain biased to GNDE, and consequently the potential of these wells will not be higher than the potential of the underlying substrate, there is no need to provide an insulation of the PMOS transistors by wells and a buried layer as illustrated in FIG. 3. The result of this is therefore a space-saving on the silicon.

The comparator CMP comprises a differential pair of input transistors T1, T2, here PMOS transistors. The gate of the transistor T2 forms a signal input ES to receive a voltage V to be compared with a reference voltage Vref received on the reference input Eref formed by the gate of the transistor T1. The reference voltage Vref is generated by a conventional voltage source, not represented in FIG. 6.

The comparator CMP also comprises an output stage ETS here comprising an inverter. This output stage comprises a signal output OUT and a complemented signal output NOUT.

The comparator CMP also comprises hysteresis-creating means coupled between the differential input pair T1 and T2 and the output stage ETS.

These hysteresis-creating means here comprise a differential pair of transistors T5, T6 mounted in diode mode, that is to say having their drain coupled to their gate. The transistors T5 and T6 are here NMOS transistors.

These transistors T5 and T6 are respectively in series between the transistors T1 and T2 and the ground GNDE. The substrate CS6 of the transistor T6 is connected to the signal output OUT whereas the substrate CS5 of the transistor T5 is connected to the complemented signal output NOUT.

As will be seen below, the substrate potential (wells CS5 and CS6) of the transistors T5 and T6 is required to change. However, as indicated above, a high biasing of the well CS5 or CS6 relative to a biasing of the substrate SUB to the ground does not pose any problem because the diode NP between the well CS5 or CS6 and the substrate SUB is then a reversed diode. That being the case, a mutual insulation of the wells CS5 and CS6, for example by a P-type substrate region, will advantageously be provided.

A first auxiliary transistor T8 is connected between the signal output OUT and the ground GNDE, and forms, with the transistor T6, a first current-copying means.

A second auxiliary transistor T7 has its source connected to the ground and its gate connected to the gate of the transistor T5, and forms, with this transistor T5, a second current-copying means.

PMOS transistors T9 and T10 form a third current-copying means connected between the second current-copying means T7, T5 and the signal output OUT.

In addition to the means that have just been described, the comparator CMP conventionally comprises biasing means MPL, here comprising the transistors T20, T21, T22 and the variable resistor R.

The comparator is powered by a power supply voltage VDDE, for example 1.2 volts.

There now follows a description of the operation of the comparator of FIG. 6.

The voltage Vref, taken for example equal to VDDE/2, is applied to the input Eref. It is also assumed that, in a first stage, the voltage V applied to the signal input SE is zero.

The transistor T2 is consequently passing. The transistor T1 is also passing (the absolute value of its gate-source voltage difference Vgs is greater than the absolute value of its threshold voltage Vth) but, since the difference Vgs-Vth of this transistor T1 is less than the difference Vgs-Vth of the transistor T2, the current of intensity 21, which circulates in the transistor T22, therefore passes fully into the transistor T2 and therefore into the branch T2-T6, whereas a zero current circulates in the branch T1-T5. The transistor T1 is therefore passing with a zero current. The transistor T8 is passing, which pulls the output of the signal OUT to the ground, therefore conferring on it the “0” logic value.

The transistor T7 is blocked, as is the transistor T10.

The well CS6 is therefore biased to the ground whereas the well CS5 is biased to the power supply voltage VDDE (because it is linked to the complemented output NOUT which has the “1” logic state).

When the signal voltage V increases to reach the reference voltage Vref, two currents of intensity I circulate respectively in the branches T2-T6 and T1-T5. However, the gate voltage of the transistor T5 is less than the gate voltage of the transistor T6 because the threshold voltage of the transistor T5 is less than the threshold voltage of the transistor T6.

In practice, it will be recalled here that, since the comparator has not yet switched over, the substrate voltage CS6 of the transistor 6 is zero whereas the substrate voltage CS5 of the transistor T5 is equal to 1.2 volts (VDDE).

Because of this, the current circulating in the branch T9-T7, and consequently the current circulating through the transistor T10 (because of the current copying) is less than the current circulating in the transistor T8. The comparator CMP has therefore still not switched over.

When the signal voltage V continues to increase to exceed the reference voltage Vref by a predefined value corresponding to the hysteresis, the current in the transistor T7, and consequently the current in the transistor T10, becomes greater than the current in the transistor T8 because the gate voltage of the transistor T5 becomes greater than the gate voltage of the transistor T6.

Consequently, the signal output OUT switches over to the “1” logic state whereas the complemented signal output switches over to the “0” logic state.

The biasing of the wells CS5 and CS6 is consequently modified and the threshold voltage of the transistor T5 becomes greater than the threshold voltage of the transistor T6. This causes an increase in the gate voltage of the transistor T5. At the same time, the threshold voltage of the transistor T6 decreases since the signal output voltage OUT, and consequently the substrate voltage CS6, increases. The result thereof is consequently an even greater increase in the current circulating in the transistor T7 and, consequently, in the transistor T10, compared to the current circulating in the transistor T8.

In other words, the current circulating in the transistor T10 becomes very great compared to the current circulating in the transistor T8, which contributes to making the switchover phenomenon of the comparator CMP all the more abrupt.

Obviously, this hysteresis phenomenon during the rising phase, which has just been described, is reproduced doubly in the falling phase, that is to say when the signal voltage V drops back to become less than the reference voltage Vref. The comparator CMP does not then switch over at the reference voltage Vref but at a voltage less than the reference voltage given the value of the hysteresis.

It will therefore be noted here that the hysteresis, both during the rising phase and during the falling phase, is obtained by a threshold voltage difference between the transistors mounted in diode mode T5 and T6 by virtue of the direct biasing of their respective wells CS5 and CS6 by the potential of the signal output OUT and of the complemented signal output NOUT.

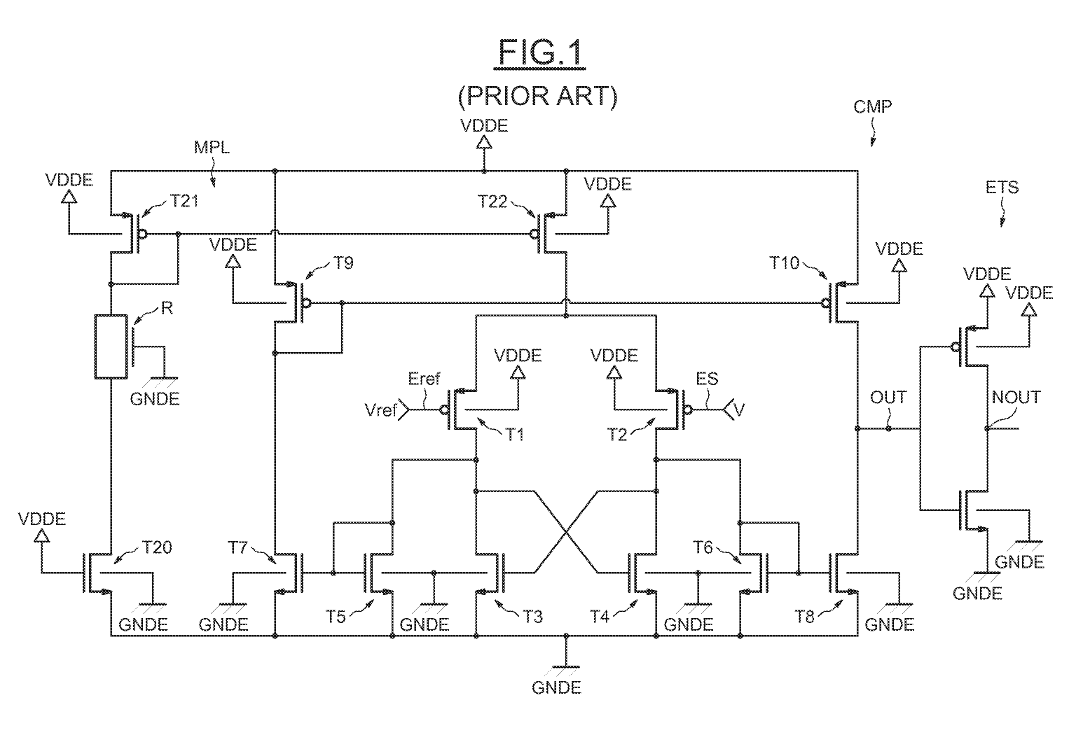

There is therefore a saving, compared to the structure of the prior art described with reference to FIG. 1, on the memory-effect transistors cross-coupled by their gates.

In the example which has just been described, the two transistors T5 and T6 had their substrates CS5, CS6 respectively coupled to the two signal outputs of the output stage. This confers a symmetrical hysteresis relative to the voltage Vref between the rising phase and the falling phase.

That being the case, it is possible to connect just one of the transistors T5 or T6 to one of the signal outputs of the output stage ETS.

More specifically, if the substrate CS5 of the transistor T5 is linked to the complemented signal output NOUT and the substrate CS6 of the transistor T6 is linked to the ground GNDE, then there will be a hysteresis in the rising phase, that is to say that the comparator will switch from the “0” logic value to the “1” logic value at the output when the signal voltage V is greater than the voltage Vref given the value of the hysteresis. By contrast, in the falling phase, the comparator will switch over when the voltage V reaches the value Vref.

On the other hand, if the substrate SC5 of the transistor T5 is linked to the ground and only the substrate CS6 of the transistor T6 is linked to the signal output OUT, a hysteresis will then be obtained which is non-symmetrical relative to the voltage Vref in the falling phase. In other words, in the rising phase, the comparator will switch from the “0” logic value to the “1” logic value when the signal voltage V reaches the value Vref.

By contrast, in the falling phase, it will switch back to the “0” state when the signal voltage V becomes equal to the voltage Vref minus the value of the hysteresis.

Although, in the embodiment of FIG. 6, it is the transistors mounted in diode mode T5 and T6 which have their wells (substrates) directly biased by the signal outputs OUT and NOUT, it would be possible, as a variant, to leave these substrates biased to the ground and to link the wells of the transistors T1 and T2 respectively to the complemented signal output NOUT and to the signal output OUT.

That being the case, a greater hysteresis value would then be obtained.

Obviously, even in this configuration, it would be possible to not link the substrate (well) of just one of the transistors T1 and T2 to the corresponding signal output and to link the well of the other transistor to the ground so as to obtain a non-symmetrical hysteresis relative to the voltage Vref.

A variant is also possible relative to the embodiment of FIG. 6.

Thus, although, in the embodiment of FIG. 6, the differential pair of the transistors mounted in diode mode comprises just two transistors T5 and T6, it is also possible to provide either greater transistor sizes for the transistors T5 and T6, or to provide for the differential pair of the transistors mounted in diode mode to comprise two groups of transistors mounted in diode mode. Each group of transistors T5 can then comprise a number of transistors T5 mutually connected in parallel and the group of transistors T6 then comprises the same number of transistors T6 mutually connected in parallel.

This makes it possible to increase the value of the hysteresis.

It is also possible to reduce the value of the hysteresis. In this respect, one possible solution is to replace each transistor T5 and T6 with two half-size transistors T5a, T5b and T6a and T6b, connected in parallel, to link the substrate of one of the transistors T5a to the node NOUT and the substrate of the other transistor T5b to the ground, and to link the substrate of the matching transistor T6a to the node OUT and the substrate of the other matching transistor T6b to the ground. Thus, virtually without changing the size of the comparator, a lower hysteresis value is obtained.

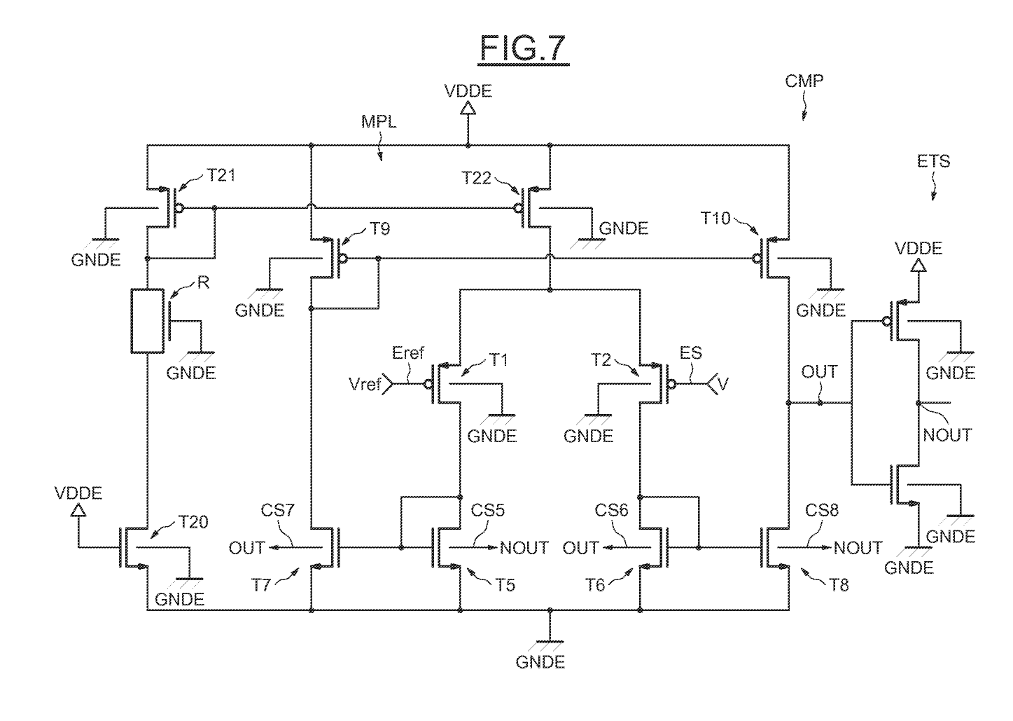

The embodiment of FIG. 7 is distinguished from the embodiment of FIG. 6 by the fact that this time, not only the transistors T5 and T6 have their wells linked to the signal outputs NOUT and OUT, but also the transistors T8 and T7.

More specifically, the auxiliary transistor T8, which is linked to the transistor T6 mounted in diode mode that has its well CS6 linked to the signal output OUT, has its well CS8 linked to the complemented signal output.

Similarly, the auxiliary transistor T7, which is connected to the transistor mounted in diode mode T5 that has its well CS5 linked to the complemented signal output NOUT, has its well CS7 linked to the signal output OUT.

Such an embodiment makes it possible to add to the hysteresis value obtained in the embodiment of FIG. 6 an additional hysteresis value obtained by the change of threshold voltages (in opposite directions) of the transistors T7 and T8.

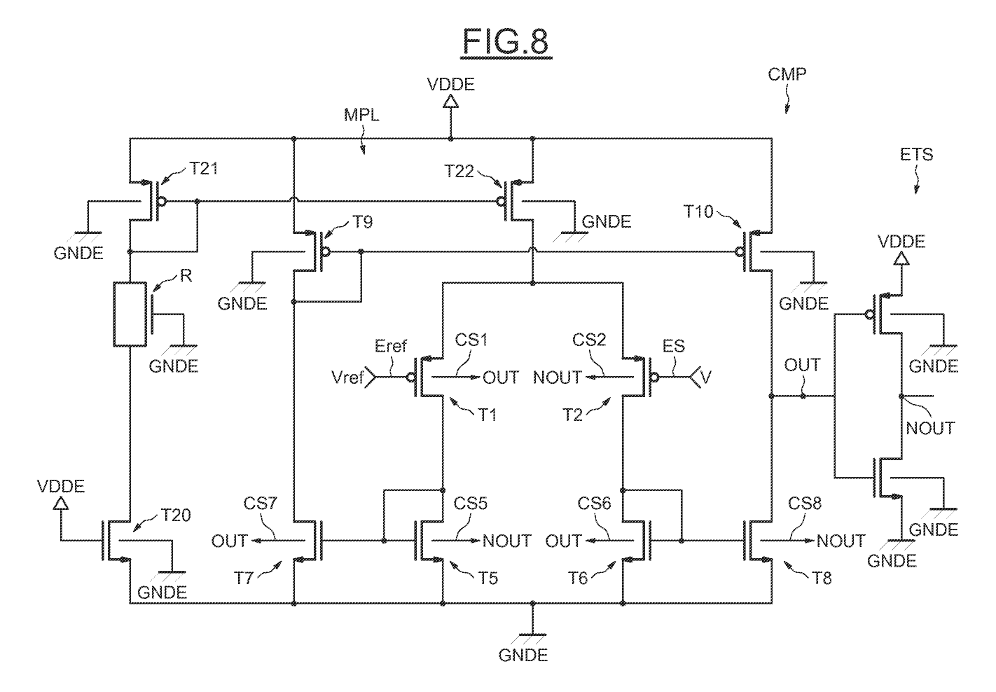

Compared to the embodiment of FIG. 7, the one illustrated in FIG. 8 comprises input transistors T1 and T2 that also have their wells CS1 and CS2 linked to the two signal outputs of the stage ETS.

More specifically, the input transistor T1, which is linked to the transistor T5 that has its well CS5 linked to the complemented signal output NOUT, has its well CS1 linked to the signal output OUT whereas the transistor T2, which is linked to the transistor T6 that has its well CS6 linked to the signal output OUT, has its well CS2 linked to the complemented signal output NOUT.

Such an embodiment once again makes it possible to increase the hysteresis of the comparator. This is because the change of biasing of the wells of the transistors T1 and T2 induces a shift towards higher hysteresis values because, when the current which circulates in the transistor T2 when the input voltage V is zero, the threshold voltage of T2 is greater as an absolute value than that of T1 and, consequently, it will be necessary to provide a higher voltage V than in the embodiment of FIG. 6 to have the current from T2 switched over to T1.

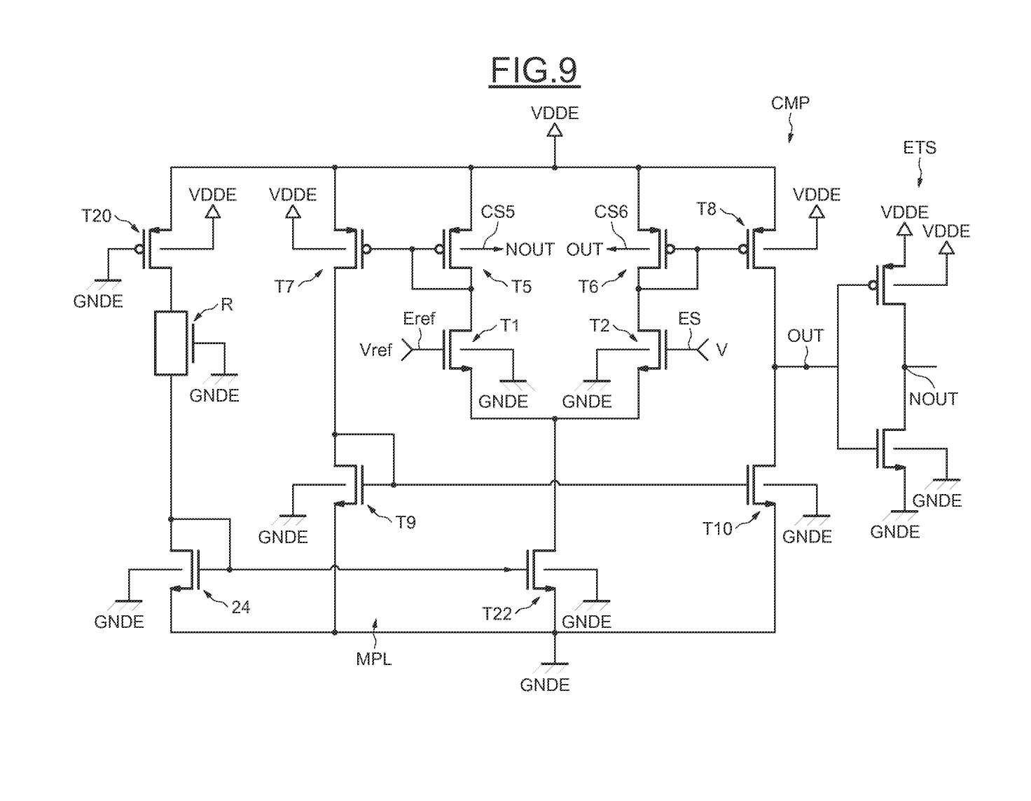

In the embodiment illustrated in FIG. 9, the transistors of the differential pair T1 and T2 are this time NMOS transistors, and the comparator is here produced in an FD SOI with no flip well technology.

The transistors T5 and T6 mounted in diode mode are therefore this time PMOS transistors as are the transistors T7 and T8. The wells CS5 and CS6 of the transistors T5 and T6 are linked respectively to the complemented signal output NOUT and to the signal output OUT.

The wells of the other PMOS transistors are linked to the power supply voltage VDDE.

The hysteresis is obtained in a manner similar to what was described with reference to FIG. 6.

The invention is not limited to the embodiments which have just been described, but encompass all the variants.

Thus, the embodiments which have been illustrated in a “flip well” FDSOI technology can be modified to a “no flip well” FDSOI technology, and vice versa.

What is claimed is:

1. An integrated comparator with hysteresis, comprising:
a differential pair of input transistors;
an output stage comprising a signal output and a complemented signal output;
a pair of transistors each mounted in diode mode and coupled between the differential pair of input transistors and the output stage;
a silicon on insulator type structure integrating said differential pair of input transistors, output stage and pair of transistors mounted in diode mode; and
a hysteresis-creating circuit comprising a circuit connection of at least one of said signal output or complemented signal output to a substrate of the silicon on insulator type structure associated with at least one transistor of the differential pair of transistors or pair of transistors mounted in diode mode.

2. The comparator according to claim 1, wherein the transistors mounted in diode mode are of a first conductivity type and the transistors of the differential pair of input transistors are of a second, opposite, conductivity type.

3. The comparator according to claim 1, further comprising a first auxiliary transistor connected between a first one of the pair of transistors mounted in diode mode and the signal output, said first auxiliary transistor and first one of the pair of transistors mounted in diode mode connected in a current mirror configuration.

4. The comparator according to claim 3, wherein said hysteresis-creating circuit further comprises a circuit connection of at one of said signal output or complemented signal output to a substrate of the silicon on insulator type structure associated with said first auxiliary transistor.

5. The comparator according to claim 4, wherein one of said signal output or complemented signal output is coupled to the substrate of the silicon on insulator type structure associated with the first one of the pair of transistors mounted in diode mode and the other of said signal output or complemented signal output is coupled to the substrate of the silicon on insulator type structure associated with the first auxiliary transistor.

6. The comparator according to claim 3, further comprising a second auxiliary transistor connected between a second one of the pair of transistors mounted in diode mode and the signal output, said second auxiliary transistor and second one of the pair of transistors mounted in diode mode connected in a current mirror configuration.

7. The comparator according to claim 6, wherein said hysteresis-creating circuit further comprises a circuit connection of at one of said signal output or complemented signal output to a substrate of the silicon on insulator type structure associated with said second auxiliary transistor.

8. The comparator according to claim 7, wherein one of said signal output or complemented signal output is coupled to the substrate of the silicon on insulator type structure associated with the second one of the pair of transistors mounted in diode mode and the other of said signal output or complemented signal output is coupled to the substrate of the silicon on insulator type structure associated with the second auxiliary transistor.

9. The comparator according to claim 6, further including a current mirror circuit coupled between said second auxiliary transistor and said signal output.

10. The comparator according to claim 1, wherein one of said signal output or complemented signal output is coupled to the substrate of the silicon on insulator type structure associated with a first one of the pair of transistors mounted in diode mode and the other of said signal output or complemented signal output is coupled to the substrate of the silicon on insulator type structure associated with a second one of the pair of transistors mounted in diode mode.

11. The comparator according to claim 1, wherein said hysteresis-creating circuit further comprises a circuit connection of at one of said signal output or complemented signal output to a substrate of the silicon on insulator type structure associated with at least one transistor of the differential pair of input transistors.

12. The comparator according to claim 11, wherein one of said signal output or complemented signal output is coupled to the substrate of the silicon on insulator type structure associated with a first one of the differential pair of input transistors and the other of said signal output or complemented signal output is coupled to the substrate of the silicon on insulator type structure associated with a second one of the differential pair of input transistors.

13. The comparator according to claim 1, wherein the transistors of the differential pair of input transistors are PMOS transistors and the pair of transistors mounted in diode mode are NMOS transistors.

14. The comparator according to claim 1, wherein the transistors of the differential pair of input transistors are NMOS transistors and the pair of transistors mounted in diode mode are PMOS transistors.

15. The comparator according to claim 1, wherein the silicon on insulator type structure is a fully depleted silicon on insulator type structure.

16. A method, comprising:
receiving input signals at inputs of a differential amplifier circuit functioning as a comparator and generating an output signal and a complemented output signal; and
creating hysteresis in the comparator by applying at least one of said output signal or complemented output signal to a substrate of a silicon on insulator type structure integrating said differential amplifier circuit.

17. The method of claim 16, wherein applying comprises applying said at least one of said output signal or complemented output signal to a doped well of the substrate of a silicon on insulator type structure, said doped well located below a transistor of the differential amplifier circuit.

18. A circuit, comprising:
a differential amplifier circuit configured to function as a comparator and generate an output signal and a complemented output signal, said differential amplifier circuit including a transistor having a gate, a source, a drain and a well;
a silicon on insulator type structure integrating said differential amplifier circuit, said silicon on insulator type structure include a first semiconductor layer including said source and drain, a second semiconductor layer including said well, and an insulating layer separating said first and second semiconductor layers; and
a hysteresis-creating circuit comprising a circuit connection of at least one of said signal output or complemented signal output to the well in the second semiconductor layer.

19. The circuit of claim 18, wherein said transistor is an input transistor of a differential pair of input transistors for the differential amplifier circuit.

20. The circuit of claim 18, where said transistor is a transistor in a current mirror circuit for the differential amplifier circuit.
